(19) United States
(12) Patent Application Publication
(10) Pub. No.: US 2016/0146748 A1
(43) Pub. Date: May 26, 2016

(54) RADIO FREQUENCY BIO-SENSOR

(71) Applicant: E I DU PONT DE NEMOURS AND COMPANY, Wilmington, DE (US)

(72) Inventors: Nigel Forest REUEL, Chadds Ford, PA (US); Joseph C. McAuliffe, Sunnyvale, CA (US)

(21) Appl. No.: 14/872,178

(22) Filed: Oct. 1, 2015

Related U.S. Application Data
(60) Provisional application No. 62/082,155, filed on Nov. 20, 2014.

(51) Int. Cl. G01N 27/02; G01R 23/02; H01G 7/00

(52) U.S. Cl. CPC G01N 27/025; H01G 7/00; G01R 23/02

(57) ABSTRACT

A radio frequency (RF) bio-sensor responsive to an analyte of interest comprising an antenna (inductor) integral with a bio-based capacitor, wherein the sensor changes resonant frequency in the presence of the analyte by biologically mediated changes to the capacitor structure and/or materials. The RF biosensor can be interrogated with a vector network analyzer to detect the resonant frequency shift.

### TECHNICAL FIELD

A radio frequency (RF) bio-sensor responsive to an analyte of interest comprising an antenna (inductor) integral with a bio-based capacitor, and more particularly such a sensor which is passive and chipless, wherein the sensor changes resonance frequency in the presence of the analyte by biologically mediated changes to the capacitor structure and/or materials.

### BACKGROUND

Human performance monitoring is a growing trend in government and consumer markets. In government applications, for example, real-time monitoring of the health of soldiers and pilots can lead to better efficiencies and protection to both the soldier and military capital. The remarkable growth trend in consumer health care sensors for individuals has risen from athletic monitors and is now spurred by new digital and social media applications to monitor, share, and improve on personal goals. There is also an increasing interest from industry to analyze and monetize individual health trends.

The first step of performance monitoring is sensing a relevant physiological change or biomarker and then transducing this sensing event to a readable format (i.e. an electronic signal). Sensors are preferably high in sensitivity, selectivity, and stability as well as low in false alarms, cost, and power consumption.

There is a need for, and it is an object of this invention to provide, improved sensors for health and performance monitoring as well as other applications.

### SUMMARY

A RF bio-sensor for detecting an analyte of interest, said sensor comprising an antenna integral with a bio-based capacitor; wherein:

the capacitor comprises a layer of bio-based medium between a first and second capacitor plate and which capacitor has an initial (first) capacitance;

the bio-based medium is responsive to the analyte of interest and provides a response in the presence of the analyte which causes the capacitor to have a second capacitance which is different from the first capacitance; and,

the RF bio-sensor has an initial resonance at the first capacitance and a second resonance at the second capacitance, which second resonance is different from the initial resonance.

The bio-sensor can be passive or chipless, or both passive and chipless.

### BRIEF DESCRIPTION OF THE DRAWINGS

FIG. 1 depicts an integral antenna and bio-based capacitor unit according to one embodiment.

FIG. 2 depicts a cut away view of a bio-based capacitor according to one embodiment.

FIG. 3 depicts an integral antenna and bio-based capacitor unit adhered to a subject.

FIG. 4 depicts a scheme for detecting a shift in resonant frequency of an integral antenna and bio-based capacitor unit.

FIG. 5 shows the inductive coil pattern with connected capacitor plates used in the Example.

FIG. 6 shows a photograph of the printed coils and capacitor plates as made in the Example.

FIG. 7 shows a photograph of the finished device as made in the Example.

FIG. 8 shows a photograph of the interrogation of the bio-sensor as performed in the Example.

FIG. 9 shows the test results of bio-sensor Device 1 from the Example.

FIG. 10 shows the test results of bio-sensor Device 2 from the Example.

FIG. 11 shows the test results of bio-sensor Device 3 from the Example.

### DESCRIPTION OF EMBODIMENTS

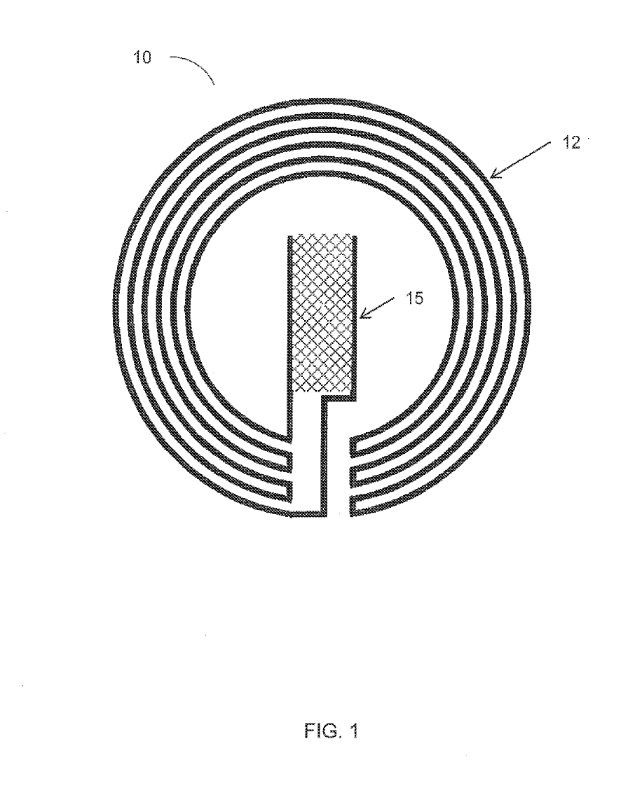

Referring to FIG. 1, there is depicted an integral antenna and bio-based capacitor unit, 10, of an RF bio-sensor according to one embodiment, with the antenna, 12, in electrical communication with the bio-based capacitor, 15. For a given antenna, the resonant frequency of the unit will vary depending on the capacitance of the bio-based capacitor.

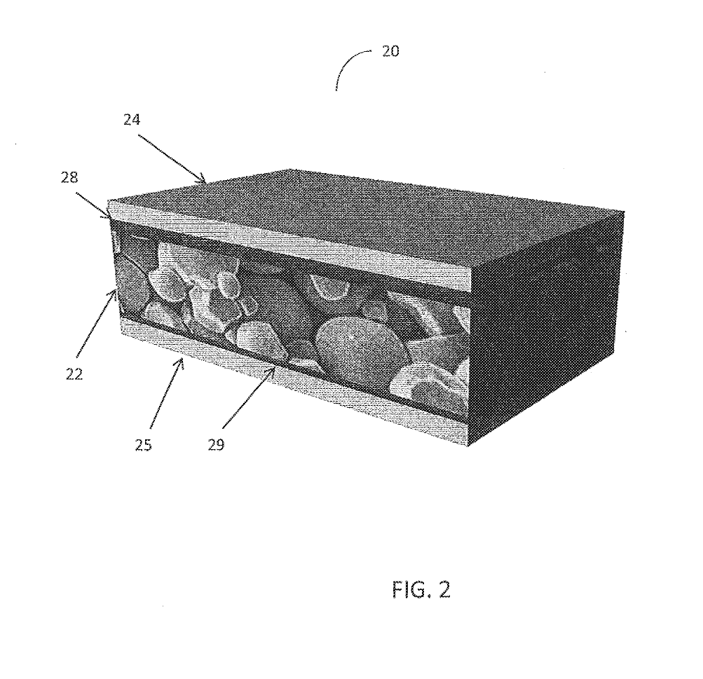

Referring to FIG. 2, there is depicted a cut away view of a bio-based capacitor, 20, with a bio-based medium, 22, between a first capacitor plate, 24 and a second capacitor plate, 25, but further comprising a first insulating layer, 28, between the bio-based medium and first capacitor plate and a second insulating layer, 29, between the bio-based medium and second capacitor plate.

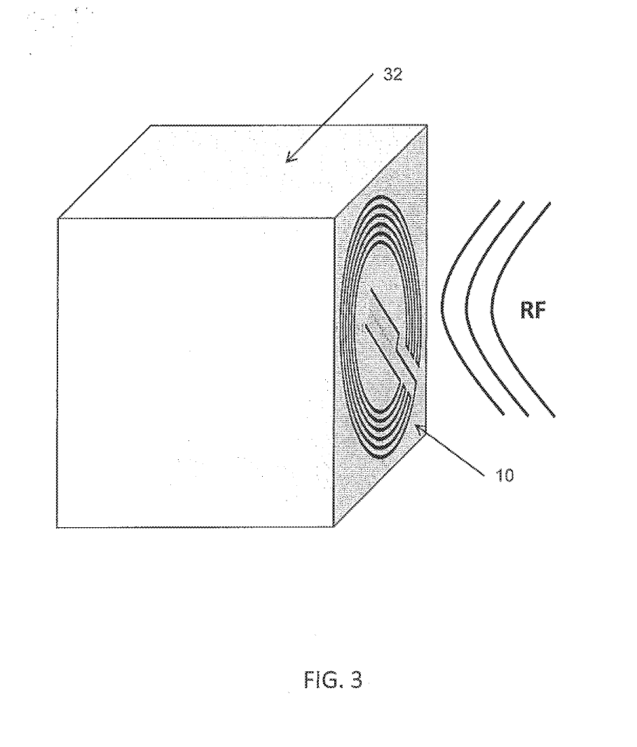

Referring to FIG. 3, there is depicted an embodiment wherein an integral antenna and bio-based capacitor unit, 10, is adhered to a subject to be tested, 32, to test for an analyte of interest. There is communication (not shown) between the subject to be tested and the bio-based capacitor so that the analyte of interest, if present, can contact the bio-based medium.

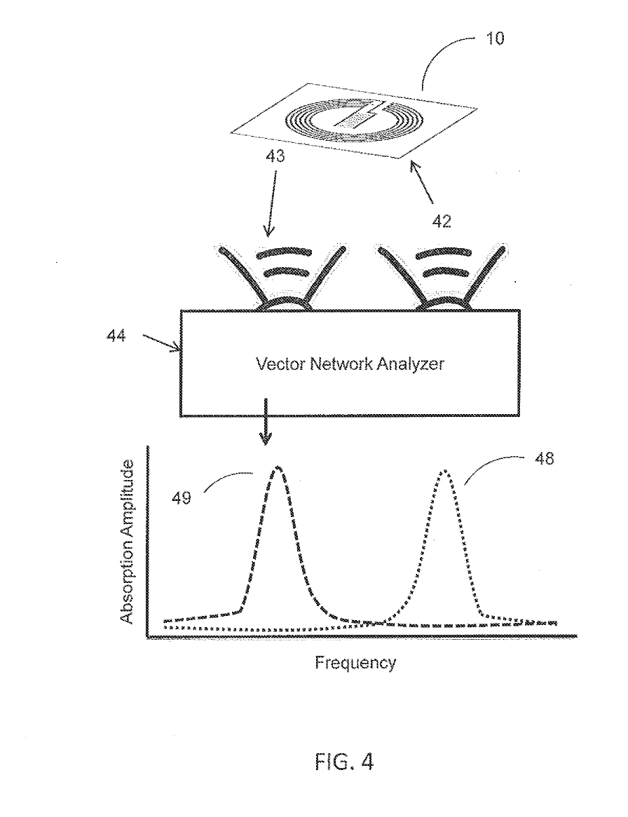

Referring to FIG. 4, there is depicted an embodiment of a readout mechanism wherein an integral antenna and bio-based capacitor unit, 10, is probed by pinging the unit at key frequencies, 42, and listening to the absorbed spectrum, 43, with a vector analysis network, 44. The analyzer interprets the spectra and reports a shift in resonant frequency, from the initial resonant frequency, 49, to a second frequency, 48, when the bio-based medium responds to an analyte. The shift in frequency can be in either direction depending on the design of the bio-based capacitor.

The analyte of interest can be any suitable analyte, especially a bio-sourced or bio-related analyte. The analyte of interest can be, for example, a component of sweat, such as sweat from a human subject.

The RF bio-sensor can be adhered to or placed in close proximity to the subject, such as a human subject, and the analyte of interest, which can be a component of sweat, can communicate with the bio-based medium by physical contact of the analyte or sweat with the bio-based medium.

The response of the bio-based medium to the presence of the analyte of interest causes a change in the capacitance of the capacitor in which it is contained. The bio-based medium makes up some or all of the dielectric medium between the first and second capacitor plates and can change the capacitance of the bio-based capacitor by, for example, changing dielectric permittivity in response to the presence of analyte.

The bio-based medium can also change the capacitance of the bio-based capacitor by, for example, expanding or contracting the separation of the first and second capacitor plates. The change in capacitance can also be affected by a combination of change in dielectric permittivity and change in capacitor plate separation. A bio-based capacitor as referred to herein means a capacitor comprising a bio-based medium.

The bio-based medium typically comprises at least one bio-based component, but need not be entirely comprised of biologically based materials. In some embodiments, the bio-based medium comprises an enzyme, which enzyme is selective for the analyte of interest. The contact of analyte with analyte-selective enzyme in the bio-based medium can trigger a response which changes the capacitance of the bio-based capacitor. In some embodiments, this response involves the enzymatic alteration of a dielectric material, which can be either bio-derived or synthetic, resulting in a change in the dielectric constant of the bio-based medium.

In some embodiments, there is an insulating layer between the bio-based medium and a capacitor plate. The insulating layer protects the capacitor plates from shorting, or passing current directly, when the substrate material is sufficiently degraded. This allows an end resonant frequency to be reported rather than a complete turn off of the device. The insulating layer can be designed from many materials such as ethylene propylene polymers or polydimethylsiloxane (PDMS).

Methods for fabricating a RF antenna and integral capacitor are well known to those skilled in the art, and such methods can be readily adapted to the placement of a layer of bio-based medium between the capacitor plates of the capacitor to make the RF sensor unit. The fabrication methods include printing, such screen printing or inkjet printing, of the required features. The antenna and capacitor plates are conductive and can comprise Cu, Ag, Fe, Mg, Zn, and alloys thereof.

The bio-sensor unit can be fabricated on a substrate which substrate may become part of the final bio-sensor unit or may simply be a transfer strip which allows fabrication and then is removed when the sensor unit is transferred to the test subject. The substrate can be flexible, such as a plastic sheet or a bandage-like strip.

The RF bio-sensor can be interrogated, for example, with a single or double antenna spectrum analyzer (vector network analyzer). For a double antenna analyzer, one antenna is used to drive a spectrum of RF frequencies and a second antenna is used to read feedback from the RF bio-sensor in the form of absorbed or reflected frequencies. The analyzer will detect signatures for resonant frequency peaks and will monitor how they shift over time, as depicted in FIG. 4. Network analyzers are commercially available, for example, from Keysight Technologies, Santa Rosa, Calif., and Rhode and Schwarz, Munich, Germany.

In some embodiments, the response of the bio-based medium to the presence of analyte of interest is degradation of the medium. For example, if the analyte of interest is calcium, the bio-based medium can comprise amylase or protease enzyme and starch. The presence of calcium can induce the enzyme to degrade the starch which in turn can change the dielectric constant of the medium and the capacitance of the bio-based capacitor.

The degradation of a compacted starch medium can be tuned to decrease the displacement of the capacitor plates. The number of activated enzymes, dictated by the concentration of the calcium in the sweat, controls the rate of the response. The separated capacitor plates reduce displacement as the compacted starch is degraded and shorter cleaved sugar fragments void to a fraction of the original volume. As each layer of starch is degraded there is an increasing volume of water between the insulated capacitor plates. This causes the dielectric material permittivity to move towards that of a water dielectric (relative permittivity about 80). The effect of substrate height and water content (d and ε respectively from the equation of capacitance: C=(ε*A)/d) provide various mechanisms for changing the resonant frequency at physiologically relevant concentrations of Ca²⁺ concentration.

In some embodiments, the response of the bio-based medium to the presence of an analyte of interest is to generate a secondary species which catalyzes a change in capacitance. For example, if the analyte of interest is lactic acid, the bio-based medium can comprise lactate oxidase enzyme which, in the presence of lactic acid, can generate hydrogen peroxide which then serves as a catalyst in a polymerization reaction which can in turn arrest a swelling mechanism, such as a hydrogel expansion.

In some embodiments, the response of the bio-based medium to the presence of an analyte of interest is to generate a gas. For example, when the analyte of interest is urea, the biobased medium can contain urease enzyme which, in the presence of urea, produces carbon dioxide as a gaseous byproduct. The gas production can then change the displacement of the capacitor plates and consequently, the capacitance of the bio-based capacitor.

Although various mechanisms for affecting capacitance change are described for illustration, a given embodiment is not bound to any particular mechanism of capacitance change except and unless that mechanism is specifically recited.

In some embodiments, the RF bio-sensor is a “passive” device, which is to say it comprises no internal power source. In some embodiments the RF bio-sensor is “chipless” which is to say that it comprises no memory chip or integrated circuit. In some embodiments the RF bio-sensor is passive and chipless.

A RF bio-sensor can made, for example, according to the following general method. An inductive ink (tuned for magnetic resonance) can be screen printed on a flexible substrate to form a planer antenna and bio-based capacitor unit (similar to that depicted in FIG. 1) such as polyimide film. The printed antenna geometry can allow for capacitor material to be printed between two capacitor plates. The bottom capacitor plate can printed first, followed, in appropriate order, by printed layers of bio-based medium and insulating layers. The top capacitor plate can then be printed with interconnection to the antenna. The amount and dielectric nature of the capacitor material, the geometry of the capacitor plates, and the geometry of the printed antenna can be preselected to produce a suitable starting resonant frequency in an open ISM band (e.g. 6.78, 13.56, 27.12, or 40.68 MHz). The response of the bio-based medium to analyte can be adjusted to causes a predictable change in capacitance and shift in resonance to another open ISM band. The RF bio-sensor can be packaged, for example, in a laminated sticker or bandage with laser etched pores to allow for liquid analyte uptake. In operation, the packaged bio-sensor can be applied, for example, to the skin of a human subject to monitor sweat for an analyte of interest.

### EXAMPLE

### Preparation of a RF Bio-Sensor

Identity of commercial materials is as follows: Silver flakes, P3093, from DuPont MicroCircuit Materials; glass frit, F4931, from DuPont MicroCircuit Materials; rosin, PV17A formulation, from DuPont MicroCircuit Materials; Collagen, ZIP-col collagen film starter pack, from Zip-NET Inc; and, Subtilisin, P5380, from Sigma.

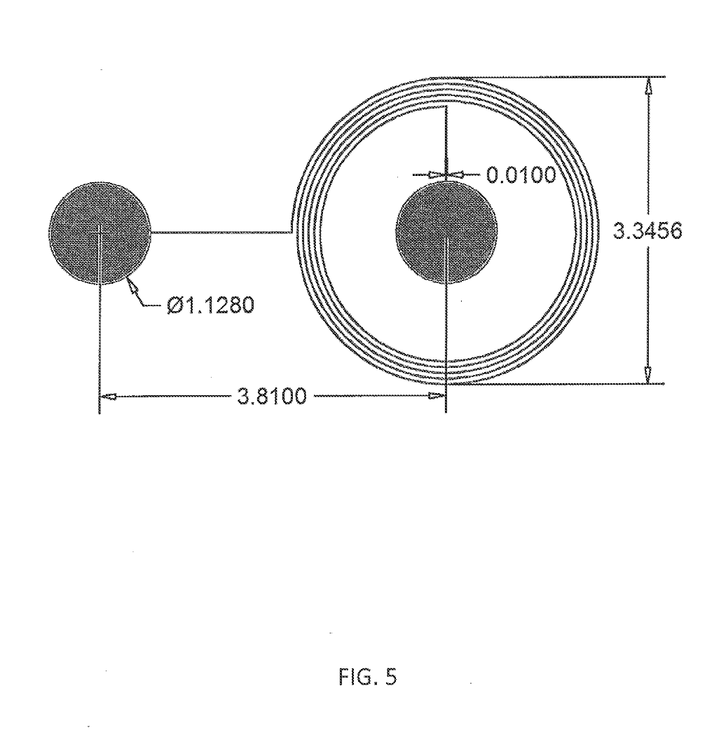

A spiral pattern inductive coil with connected capacitor plates was screen printed onto a Kapton® polyimide sheet using a silver paste. The coil pattern is shown in FIG. 5 wherein key dimensions are given in cm. Line widths are 100 μm, spacing between coils is 524 μm.

The silver paste was prepared as follows. In a jar, 97 parts by weight of 3 μm silver flakes and 3 parts by weight glass ceramic frit were combined and tumbled for 30 minutes to ensure thorough mixing. An organic medium comprised of ester alcohol, ester compounds, and hydrogenated rosin was separately prepared; the mixture of silver flake and frit (120 g) was added to the organic medium (20 g) in five portions (20 g silver mixture in each portion) with centrifugal mixing (1 min at 1000 rpm) after each addition, thereby producing a paste with a final loading of 89 weight % solids. The paste was 3-roll milled using a 25 μm gap, with 3 passes at 0 psi and 3 passes at 100 psi. The viscosity of the paste was measured with a Brookfield DV-I Prime viscometer using an S14 spindle at 10 rpm and adjusting to a value of 218 PaS by adding Texanol (trimethyl hydroxypentyl isobutyrate) solvent.

The silver paste was printed on 3 inch by 3.5 inch Kapton® polyimide coupons (100 μm thick) using an HMI (model # MSP465) screen printer equipped with a 400 mesh stainless steel screen (MicroScreen LLC, 0.8 emulsion, 80 μm line). The paste was laid down in print/flood mode in a single pass. The printed inductive coils were dried at 350° C. for 30 minutes in air.

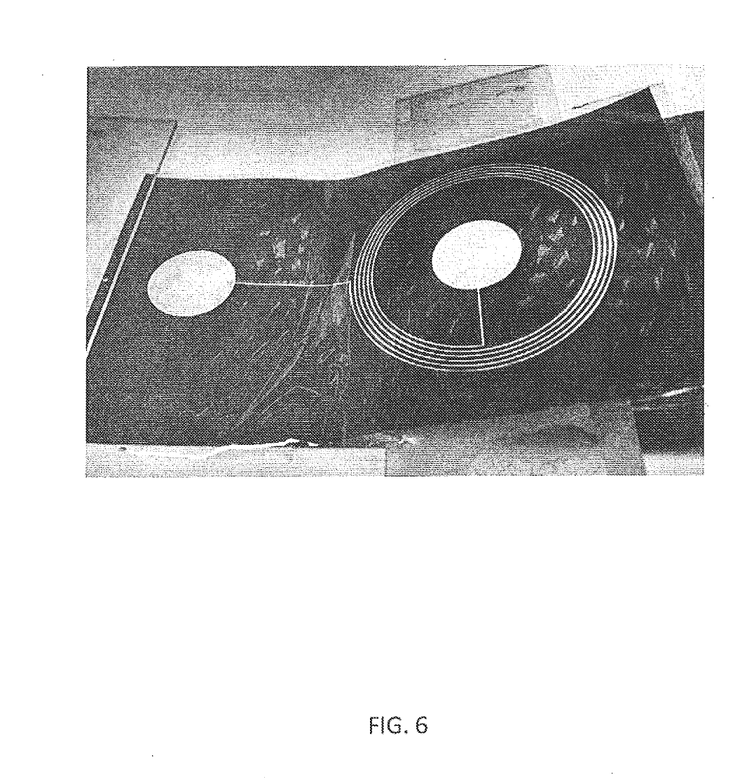

The printed coils and capacitor plates were insulated with a 75 μm layer of low density poly ethylene (LDPE) film which was positioned on top the print and pressed into place to provide good adherence. FIG. 6 shows is a photograph of the printed coils and capacitor plates “sandwiched” between the Kapton® substrate and LDPE insulating layer.

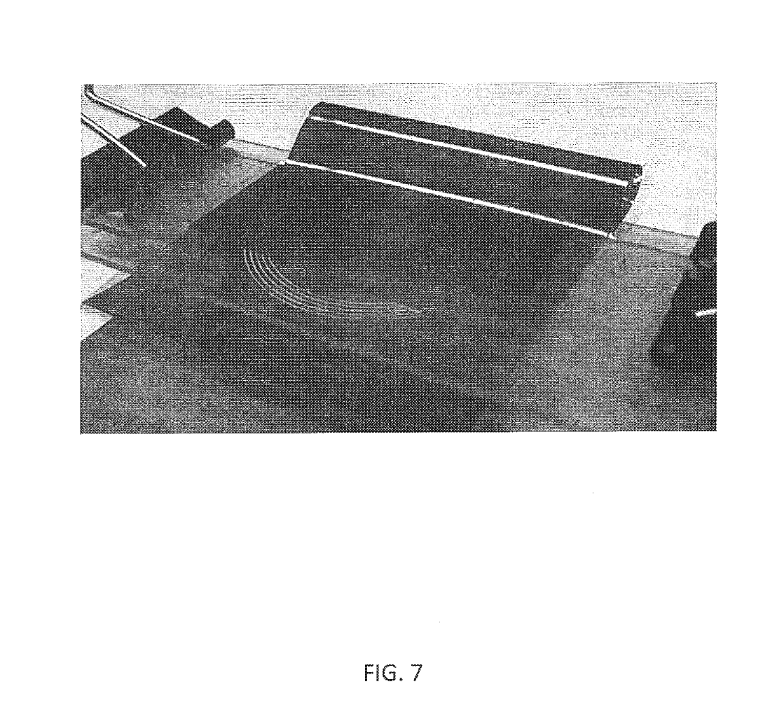

The finished bio-sensor device was prepared by placing the dielectric substrate on the insulated capacitor plate in the center of the spiral coil and folding the print in half so that the second capacitor plate lays on top of the dielectric substrate thus completing the capacitor. The capacitor plates were secured between two glass microscope slides which kept the capacitor plates firm and in planar position to the dielectric. FIG. 7 shows is a photograph of the finished device just described. The capacitor is arranged in a manner similar to that depicted in FIG. 2.

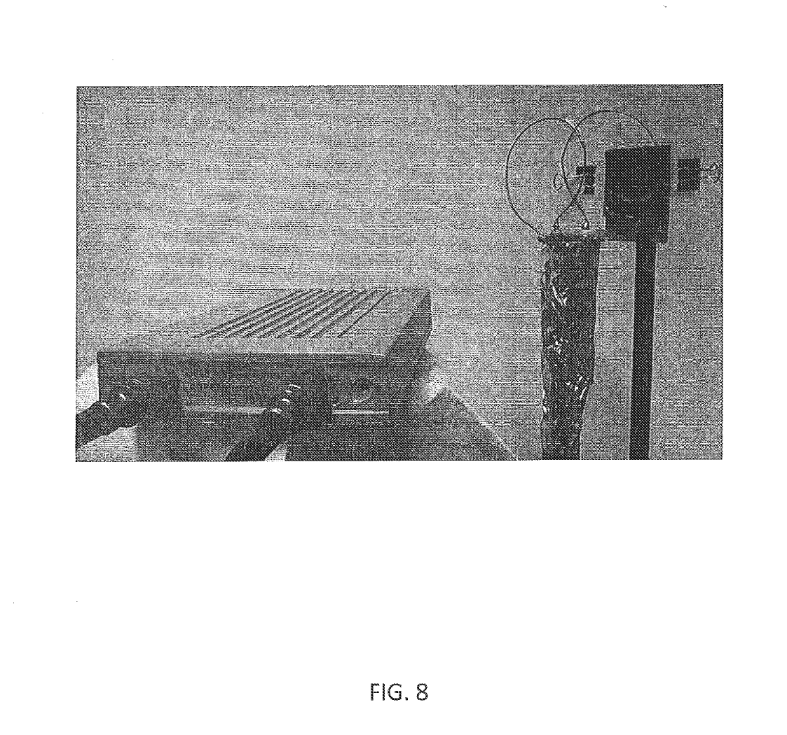

The wireless signal from the device was interrogated with two port vector network analyzer (“VNA”) (Copper Mountain Technologies, model S5048) to observe the starting resonant frequency and subsequent shift in the resonant peak as dielectric material changes in response to the analyte. The VNA was connected to a custom, two-loop transmitter-receiver antenna formed from copper wires with a mutual ground. The antennas and wireless sensor were supported on plastic (Delrin® acetal homopolymer) rods connected to an optic stage track for displacement measurement. FIG. 8 shows a photograph of the interrogation arrangement. The data acquisition was automated with numerical and control software (MATLAB from MathWorks) acquiring an S21 measurement every 30 seconds with a range of 1 to 100 MHz, 1201 point resolution, and 10 scan averaging.

The dielectric substrate was a collagen film (50 μm) infused with a Subtilisin protease enzyme. This was cut to 1″×1″ size for placement between the capacitor plates. The Subtilisin is activated by calcium and when activated, digests the collagen which in turn changes the dielectric capacity of the substrate. In a typical device, there would be a fluidic pathway for contact of the calcium-containing analyte (such as human sweat) with the dielctric in the capacitor; however, for demonstration purposes in this example, the dielectric was spiked with calcium-containing analyte prior to sealing of the capacitor.

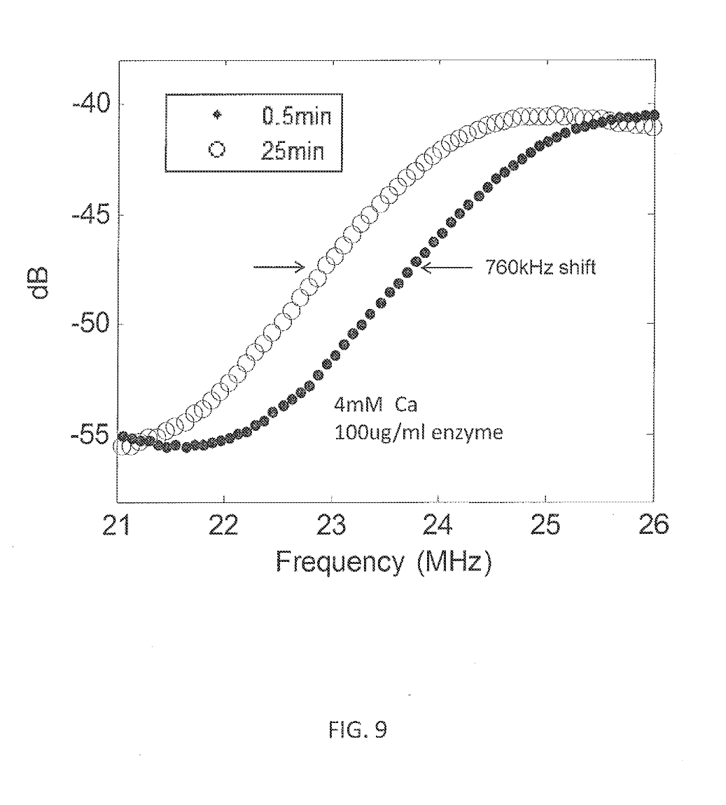

Three devices were prepared and interrogated. The dielectric in Device 1 contained collagen, subtilisin (100 ug/ml) and analyte comprising 4 mM Ca. The dielectric in Device 2 contained collagen and analyte comprising 4 mM Ca. The dielectric in Device 3 contained collagen, subtilisin (1 mg/ml) and analyte comprising 1 mM Ca. The S21 parameter measurement at 0.5 and 25 minutes for each of Devices 1-3 is shown in FIGS. 9-11, respectively.

Device 1 demonstrates the dielectric change and resulting frequency shift for collagen in the presence of a critical amount of subtilisin enzyme and calcium concentration. As shown in FIG. 9, there was a 760 kHz frequency shift, over a 25 minute period, indicating a 1.1 pF change in capacitance.

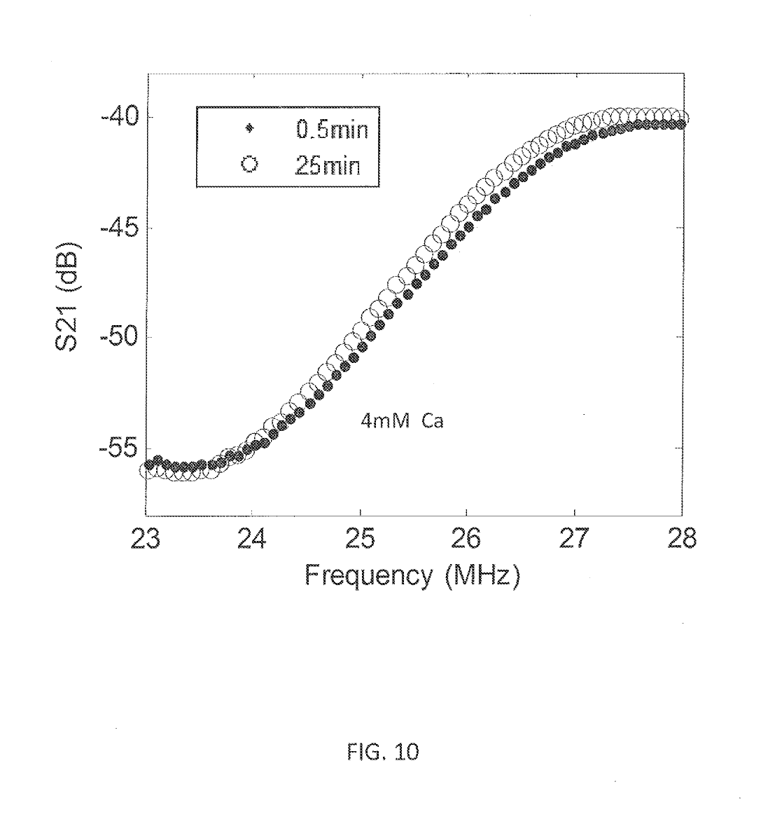

Device 2 demonstrates a lack of dielectric change and frequency shift over a 25 minute period when the collagen dielectric medium contains no enzyme. This is shown in FIG. 10 where there is substantially no difference in S21 parameter at 0.5 minutes and 25 minutes.

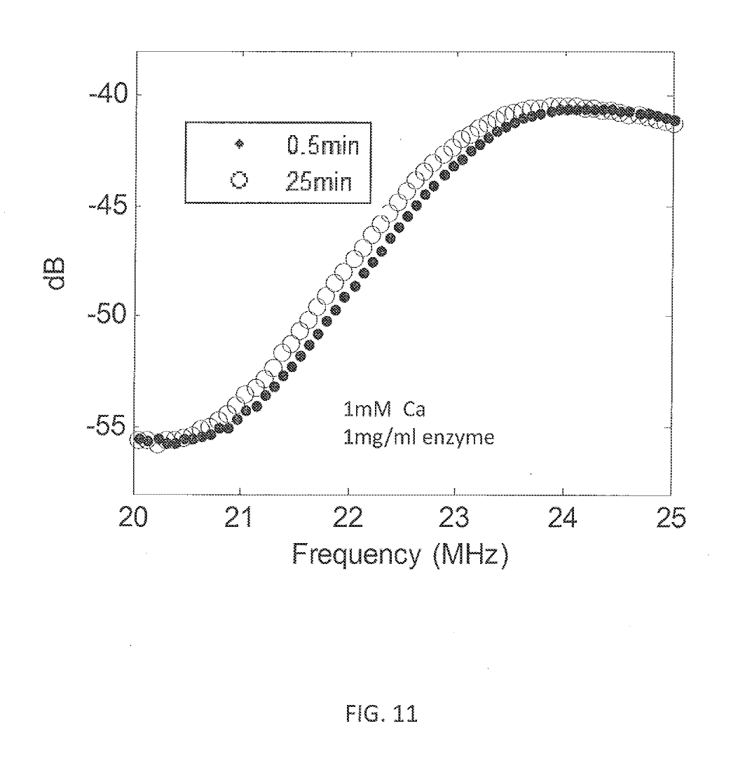

Device 3 demonstrates the lack of dielectric change and frequency shift over a 25 minute period when the collagen dielectric medium does not contain an appropriate amount of enzyme and analyte. This is shown in FIG. 11 where there is substantially no difference in S21 parameter at 0.5 minutes and 25 minutes.

Thus it is shown that a RF bio-sensor can be equipped with a dielectric medium which responds to a preselected analyte; that the response to analyte causes a change dielectric constant; and that the change in dielectric constant results in a change in resonant frequency which can be detected wirelessly by a monitoring device (vector network analyzer).

What is claimed is:

1. A RF bio-sensor for detecting an analyte of interest, said sensor comprising an antenna integral with a bio-based capacitor,
wherein:
the capacitor comprises a layer of bio-based medium between a first and second capacitor plate and which capacitor has an initial (first) capacitance;
the bio-based medium is responsive to the analyte of interest and provides a response in the presence of the analyte which causes the capacitor to have a second capacitance which is different from the first capacitance; and
the sensor has an initial resonant frequency at the first capacitance and a second resonant frequency at the second capacitance, which second resonant frequency is different from the initial resonant frequency.

2. The RF bio-sensor of claim 1 comprising no internal power source.

3. The RF bio-sensor of claim 1 comprising no integrated circuit.

4. The RF bio-sensor of claim 1 further comprising a flexible substrate

5. The RF bio-sensor of claim 1 wherein the bio based medium comprises at least one enzyme.

6. The RF bio-sensor of claim 1 wherein the analyte of interest is a component of human sweat.

7. The RF bio-sensor of claim 1 wherein the bio based medium comprises protease enzyme and collagen, and the analyte of interest is calcium.

8. The RF bio-sensor of claim 1 wherein the bio based medium comprises amylase enzyme and starch, and the analyte of interest is calcium.

9. The RF bio-sensor of claim 1 wherein the analyte of interest is lactic acid and the bio-based medium comprises lactate oxidase enzyme.

10. The RF bio-sensor of claim 1 wherein the analyte of interest is urea and the bio-based medium comprises urease enzyme.
